(19) United States
(12) Patent Application Publication
(10) Pub. No.: US 2024/0429087 A1
(43) Pub. Date: Dec. 26, 2024

(54) CHUCK TABLE AND EDGE TRIMMING APPARATUS

(71) Applicant: DISCO CORPORATION, Tokyo (JP)

(72) Inventors: Kokichi MINATO, Tokyo (JP); Atsushi KOMATSU, Tokyo (JP); Tatsuhiko MORI, Tokyo (JP)

(21) Appl. No.: 18/679,889

(22) Filed: May 31, 2024

(30) Foreign Application Priority Data
Jun. 22, 2023 (JP) 2023-102368

(51) Int. Cl. H01L 21/683; B24B 9/06; B24B 41/06; H01L 21/67

(52) U.S. Cl. CPC H01L 21/6838; B24B 9/065; B24B 41/068; H01L 21/67092

(57) ABSTRACT

A chuck table in an edge trimming apparatus includes a ring table that sucks and holds a lower surface of an outer circumferential part of the wafer by a wafer suction surface and a base table that holds the ring table in such a manner that the wafer suction surface is exposed. The base table includes a support surface that supports a lower surface of the ring table held by a ring table holding mechanism and a communicating port that is formed in the support surface and causes the wafer suction surface to communicate with a suction source. The ring table has a wafer suction hole having an opening in the wafer suction surface in such a manner as to be capable of connecting to the communicating port. The wafer suction surface is planarized by grinding the wafer suction surface by an abrasive stone.

### BACKGROUND OF THE INVENTION

### Field of the Invention

The present invention relates to a chuck table used for an edge trimming apparatus that grinds an outer circumferential part of a wafer in a ring manner and an edge trimming apparatus that grinds an outer circumferential part of a wafer in a ring manner.

### Description of the Related Art

When a wafer having an outer circumferential part beveled along the arc is ground and thinned, the thinned beveled part becomes a sharp edge, and the likelihood of the occurrence of breakage or a crack in the wafer becomes higher. Thus, a technique for preventing the formation of the sharp edge has been employed. In this technique, edge trimming to annularly remove a beveled part at the outer circumference of a wafer to a predetermined depth is executed. Thereafter, the whole of the wafer is thinned to eliminate the remaining part of the beveled part. An edge trimming apparatus that executes the edge trimming grinds an outer circumferential part of a wafer held by a chuck table in a ring manner by a grinding abrasive stone as disclosed in Japanese Patent Laid-open No. 2014-056889, Japanese Patent Laid-open No. 2015-182166, and Japanese Patent Laid-open No. 2020-040181.

In the case of the edge trimming of a bonded wafer obtained by joining two wafers, reuse of the lower wafer is enabled by grinding only the upper wafer having a beveled part at the outer circumference by the grinding abrasive stone and preventing the grinding abrasive stone from cutting into the lower wafer. However, if variation in the thickness of the lower wafer is large, it is difficult to make the cutting-in depth of the grinding abrasive stone constant in the edge trimming of the surface of the upper wafer. Thus, as disclosed in Japanese Patent Laid-open No. 2020-040181, the height of the outer circumferential part is measured while the wafer is rotated, and the grinding abrasive stone is raised and lowered to follow change in the measured height with respect to the rotation angle of the wafer. That is, the grinding abrasive stone is raised and lowered in such a manner that the distance between the holding surface and the grinding abrasive stone becomes constant when the chuck table is rotated.

### SUMMARY OF THE INVENTION

In the edge trimming method described in Japanese Patent Laid-open No. 2020-040181, grinding processing of an outer circumferential part of a wafer is executed after the height of the outer circumferential part of the wafer is measured. Therefore, the measurement time is required, and the processing time becomes long.

Thus, an object of the present invention is to provide an edge trimming apparatus that can eliminate the need for a step of measuring the height of an outer circumferential part of a wafer in a ring manner and a chuck table suitable for the edge trimming apparatus.

In accordance with an aspect of the present invention, there is provided a chuck table used for an edge trimming apparatus that grinds an outer circumferential part of an upper surface of a wafer in a ring manner by an abrasive stone and holding the wafer. The chuck table includes a ring table that sucks and holds a lower surface of the outer circumferential part of the wafer by a wafer suction surface and a base table that holds the ring table in such a manner that the wafer suction surface is exposed. The base table includes a ring table holding mechanism that holds the ring table, a support surface that supports a lower surface of the ring table held by the ring table holding mechanism, and a communicating port that is formed in the support surface and causes the wafer suction surface of the ring table to communicate with a suction source. The ring table includes a wafer suction hole having an opening in the wafer suction surface in such a manner as to be capable of connecting to the communicating port. The wafer suction surface is planarized by grinding the wafer suction surface by the abrasive stone.

Preferably, at least a front surface part of the ring table is formed of silicon. Preferably, the ring table holding mechanism includes a clamp that clamps an outer circumferential side surface or an inner circumferential side surface of the ring table and an opening-closing mechanism that opens and closes the clamp.

In accordance with another aspect of the present invention, there is provided an edge trimming apparatus including a chuck table that holds a wafer, an edge trimming mechanism that grinds an outer circumferential part of an upper surface of the wafer held by the chuck table in a ring manner by an abrasive stone, and a controller that controls the edge trimming mechanism. The chuck table includes a ring table that sucks and holds a lower surface of the outer circumferential part of the wafer by a wafer suction surface and a base table that holds the ring table in such a manner that the wafer suction surface is exposed. The base table includes a ring table holding mechanism that holds the ring table, a support surface that supports a lower surface of the ring table held by the ring table holding mechanism, and a communicating port that is formed in the support surface and causes the wafer suction surface of the ring table to communicate with a suction source. The ring table includes a wafer suction hole having an opening in the wafer suction surface in such a manner as to be capable of connecting to the communicating port. The ring table is mounted on the base table attachably and detachably.

Preferably, the ring table holding mechanism includes a table suction hole that is formed in the support surface of the base table and sucks the lower surface of the ring table, a table suction path that causes the table suction hole to communicate with a suction source, and a table suction path open/close valve disposed on the table suction path.

Preferably, a different form of the ring table holding mechanism includes a male screw formed at a lower part of an outer side surface of the ring table and a female screw that corresponds to the male screw and is formed at a lower part of an inner side surface of a recessed part in which the ring table is disposed in the base table.

Preferably, another different form of the ring table holding mechanism includes a grasping part that is disposed on the side of the base table and grasps a lower part of an outer side surface of the ring table supported by the support surface and an opening-closing unit that opens and closes the grasping part.

Preferably, the edge trimming apparatus further includes a height detector that detects the height of the wafer suction surface and the support surface. The controller has a storage section that stores the height of the support surface measured by the height detector, a thickness calculation section that calculates difference between the height of the wafer suction surface measured and the height of the support surface stored in the storage section as the thickness of the ring table when the height of the wafer suction surface is measured, and a determination section that determines a timing at which the thickness calculated by the thickness calculation section has become equal to or smaller than a threshold set in advance as a replacement timing of the ring table.

According to the chuck table and the edge trimming apparatus of the present invention, the distance between the holding surface and the lower surface of the abrasive stone during the rotation of the chuck table can be made constant. Therefore, it is possible to eliminate the need for measurement of the upper surface height of the outer circumferential part of the wafer with respect to the rotation angle of the chuck table before grinding processing of the outer circumferential part of the upper surface of the wafer held on the chuck table is executed.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of an edge trimming apparatus;

FIG. 2 is a sectional view illustrating the state in which an outer circumferential part of the upper surface of a wafer is being ground by the edge trimming apparatus;

FIG. 3 is a sectional view illustrating the state in which a wafer suction surface of a ring table is being ground by the edge trimming apparatus;

FIG. 4 is a plan view illustrating the state in which the wafer suction surface of the ring table is being ground by the edge trimming apparatus;

FIG. 5 is a sectional view of the state in which the ring table holds the wafer in a chuck table of a first embodiment;

FIG. 6 is a sectional view of the state in which the wafer is separated from the ring table in the chuck table of the first embodiment;

FIG. 7 is a perspective view of the state in which the chuck table of the first embodiment is disassembled;

FIG. 8 is a perspective view of the state in which the chuck table of the first embodiment is disassembled;

FIG. 9 is a sectional view illustrating the state in which the wafer suction surface of the ring table is being ground by an edge trimming mechanism of a modification example;

FIG. 10 is a plan view illustrating the state in which the wafer suction surface of the ring table is being ground by the edge trimming mechanism of the modification example;

FIG. 11 is a sectional view of the state in which the ring table has been removed from a base table in a chuck table of a second embodiment;

FIG. 12 is a sectional view of the state in which the ring table holds the wafer in the chuck table of the second embodiment;

FIG. 13 is a perspective view of the state in which the chuck table of the second embodiment is disassembled;

FIG. 14 is a sectional view of the state in which the ring table holds the wafer in a chuck table of a third embodiment;

FIG. 15 is a sectional view of the state in which the wafer is separated from the ring table in the chuck table of the third embodiment;

FIG. 16 is a sectional view of the state in which holding of the ring table to the base table has been released in the chuck table of the third embodiment; and

FIG. 17 is a sectional view of the state in which the ring table has been removed from the base table in the chuck table of the third embodiment.

### DETAILED DESCRIPTION OF THE PREFERRED EMBODIMENTS

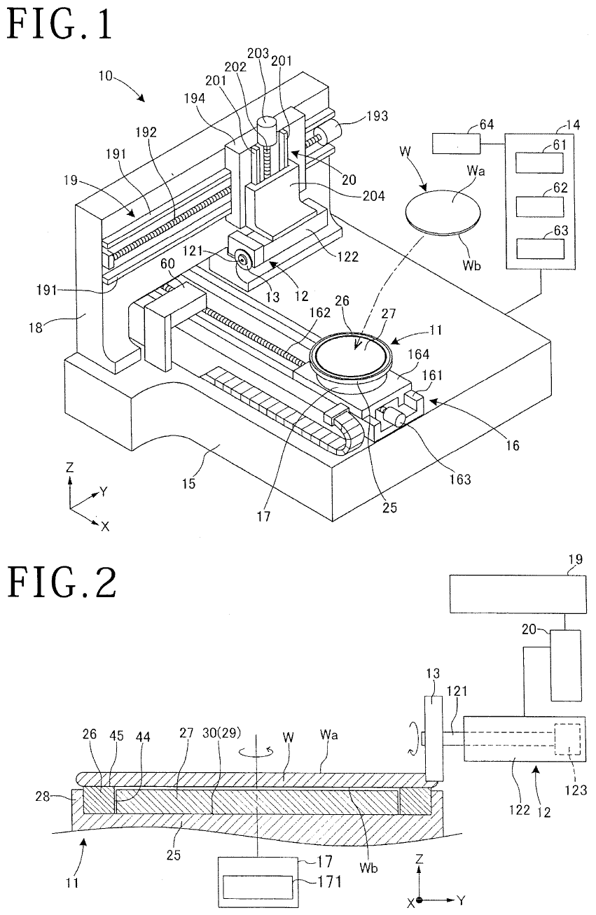

Embodiments of the present invention will be described below with reference to the accompanying drawings. FIG. 1 illustrates the overall configuration of an edge trimming apparatus 10. An X-axis direction, a Y-axis direction, and a Z-axis direction are directions perpendicular to each other. The X-axis direction and the Y-axis direction are the horizontal directions. The Z-axis direction is the vertical direction (upward-downward direction).

The edge trimming apparatus 10 is an apparatus that executes grinding processing for a wafer W held by a chuck table 11 by using an abrasive stone 13 included in an edge trimming mechanism 12 and is, more specifically, an apparatus that executes edge trimming in which an outer circumferential part of the wafer W is ground in a ring manner by the abrasive stone 13. The respective parts of the edge trimming apparatus 10 operate under control by a controller 14. The controller 14 includes a processor that executes calculation processing in accordance with a program, a memory that stores programs and various kinds of data, and so forth.

The edge trimming apparatus 10 includes an X-axis movement mechanism 16 on a base 15 and can move the chuck table 11 in the X-axis direction by the X-axis movement mechanism 16. The X-axis movement mechanism 16 has a guide part 161 and a ball screw 162 that extend along the X-axis direction, a motor 163 that rotationally drives the ball screw 162, and an X-axis table 164 supported movably in the X-axis direction through the guide part 161. The ball screw 162 is screwed to a screwing part (illustration is omitted) of the X-axis table 164. When the motor 163 is driven to rotate the ball screw 162, the X-axis table 164 moves in the X-axis direction. When the rotation direction of the ball screw 162 is reversed, the movement direction of the X-axis table 164 in the X-axis direction is switched.

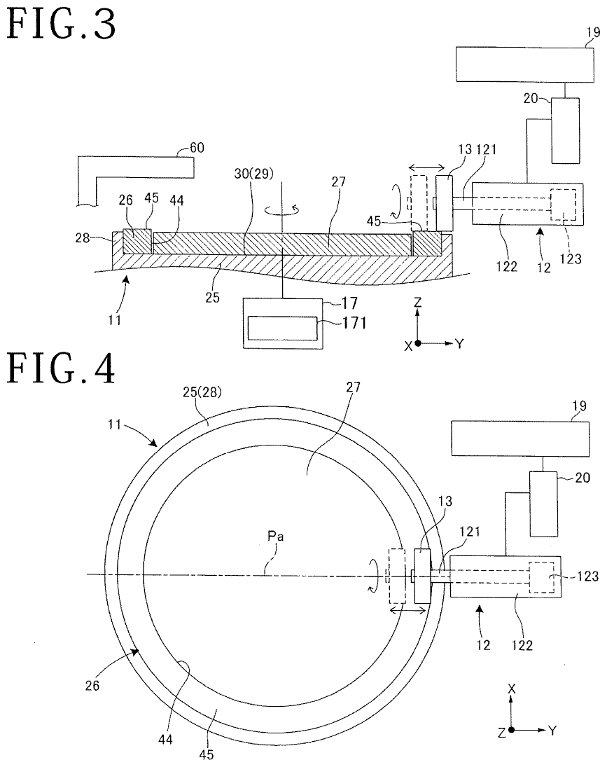

The chuck table 11 is supported rotatably around an axis extending along the Z-axis direction through a table rotation mechanism 17. The table rotation mechanism 17 includes a motor 171 (FIGS. 2 and 3). Driving the motor 171 rotates the chuck table 11.

A gate-shaped column 18 that straddles the upper side of the path of the movement of the chuck table 11 by the X-axis movement mechanism 16 is disposed on the base 15. A Y-axis movement mechanism 19 and a Z-axis movement mechanism 20 are disposed on the column 18. The Y-axis movement mechanism 19 moves the edge trimming mechanism 12 in the Y-axis direction. The Z-axis movement mechanism 20 moves the edge trimming mechanism 12 in the Z-axis direction.

The Y-axis movement mechanism 19 has a guide part 191 and a ball screw 192 that extend along the Y-axis direction, a motor 193 that rotationally drives the ball screw 192, and a Y-axis table 194 supported movably in the Y-axis direction through the guide part 191. The ball screw 192 is screwed to a screwing part (illustration is omitted) of the Y-axis table 194. When the motor 193 is driven to rotate the ball screw 192, the Y-axis table 194 moves in the Y-axis direction. When the rotation direction of the ball screw 192 is reversed, the movement direction of the Y-axis table 194 in the Y-axis direction is switched.

The Z-axis movement mechanism 20 has a guide part 201 and a ball screw 202 that extend along the Z-axis direction, a motor 203 that rotationally drives the ball screw 202, and a Z-axis table 204 supported movably in the Z-axis direction through the guide part 201. The ball screw 202 is screwed to a screwing part (illustration is omitted) of the Z-axis table 204. When the motor 203 is driven to rotate the ball screw 202, the Z-axis table 204 moves in the Z-axis direction. When the rotation direction of the ball screw 202 is reversed, the movement direction of the Z-axis table 204 in the Z-axis direction is switched.

The edge trimming mechanism 12 is supported by the lower end of the Z-axis table 204. As illustrated in FIGS. 2 to 4, in the edge trimming mechanism 12, a spindle 121 that is a rotating shaft extending along the Y-axis direction is rotatably supported in a housing 122. The spindle 121 is rotationally driven around an axis line along the Y-axis direction by a spindle motor 123. The abrasive stone 13 with a circular plate shape is attached to the tip of the spindle 121 and rotates with the spindle 121.

The wafer W is held by the chuck table 11. The detailed structure of the chuck table 11 will be described later. The chuck table 11 that holds the wafer W moves in the X-axis direction by the X-axis movement mechanism 16 and is positioned to a conveyance position and a processing position. FIG. 1 illustrates the state in which the chuck table 11 exists at the conveyance position.

In the state in which the chuck table 11 exists at the conveyance position, the wafer W can be transferred between a conveying mechanism that is not illustrated and the chuck table 11. As illustrated in FIG. 2, the outer circumferential edge of the wafer W before processing by the edge trimming apparatus 10 has been beveled into an arc shape in the thickness direction.

The conveying mechanism conveys the wafer W before processing by the edge trimming apparatus 10 and places the wafer W on the chuck table 11 existing at the conveyance position. When the chuck table 11 that holds the wafer W before processing is moved from the conveyance position to the processing position by the X-axis movement mechanism 16, the wafer W is located under the edge trimming mechanism 12. The position of the edge trimming mechanism 12 in the Y-axis direction is adjusted by the Y-axis movement mechanism 19, and the abrasive stone 13 is positioned above an outer circumferential part of the wafer W. The spindle motor 123 is driven to rotate the spindle 121 and the abrasive stone 13, and the edge trimming mechanism 12 is lowered by the Z-axis movement mechanism 20. Thereupon, as illustrated in FIG. 2, the abrasive stone 13 that rotates gets contact with the outer circumferential part of the wafer W from the side of an upper surface Wa and grinds the outer circumferential part. Thereby, grinding processing (edge trimming) to remove the beveled part from the side of the upper surface Wa of the wafer W toward the side of a lower surface Wb to a predetermined depth is executed. The edge trimming is executed while the chuck table 11 is rotated by the table rotation mechanism 17, and the outer circumferential part of the wafer W held by the chuck table 11 is removed to the predetermined depth in a ring manner by the grinding using the abrasive stone 13. Then, the step of the edge trimming is ended in the state in which part of the beveled part that has not been removed by the grinding is left on the side of the lower surface Wb of the wafer W.

After the grinding of the wafer W by the abrasive stone 13 is completed, the chuck table 11 is moved from the processing position to the conveyance position by the X-axis movement mechanism 16. The conveying mechanism receives the wafer W resulting from the processing from the chuck table 11 existing at the conveyance position and carries out the wafer W.

The wafer W after the processing by the edge trimming apparatus 10 is conveyed to a grinding apparatus that is not illustrated. In the grinding apparatus, the side of the lower surface Wb is totally ground to thin the wafer W. When the side of the lower surface Wb of the wafer W is ground, the beveled part on the side of the lower surface Wb, which is left without being removed in the previous edge trimming, is also removed at the outer circumferential part of the wafer W. Thus, formation of a sharp edge at the outer circumferential part of the wafer W can be prevented.

In the edge trimming apparatus 10, when the chuck table 11 that does not hold the wafer W is moved to the processing position by the X-axis movement mechanism 16, the chuck table 11 is located under the edge trimming mechanism 12. The position of the edge trimming mechanism 12 in the Y-axis direction is adjusted by the Y-axis movement mechanism 19, and the abrasive stone 13 is positioned above a ring table 26 (details will be described later) forming an outer circumferential part of the chuck table 11. The spindle motor 123 is driven to rotate the spindle 121 and the abrasive stone 13, and the edge trimming mechanism 12 is lowered by the Z-axis movement mechanism 20. Thereupon, as illustrated in FIGS. 3 and 4, the abrasive stone 13 that rotates gets contact with a wafer suction surface 45 that is the upper surface (front surface) of the ring table 26 and grinds the wafer suction surface 45. Thereby, surface correction processing to planarize the wafer suction surface 45 and adjust the shape thereof is executed.

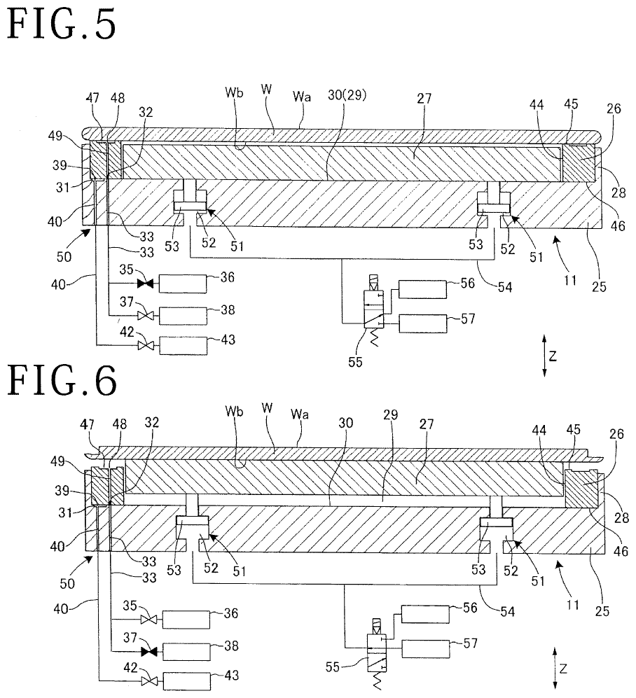

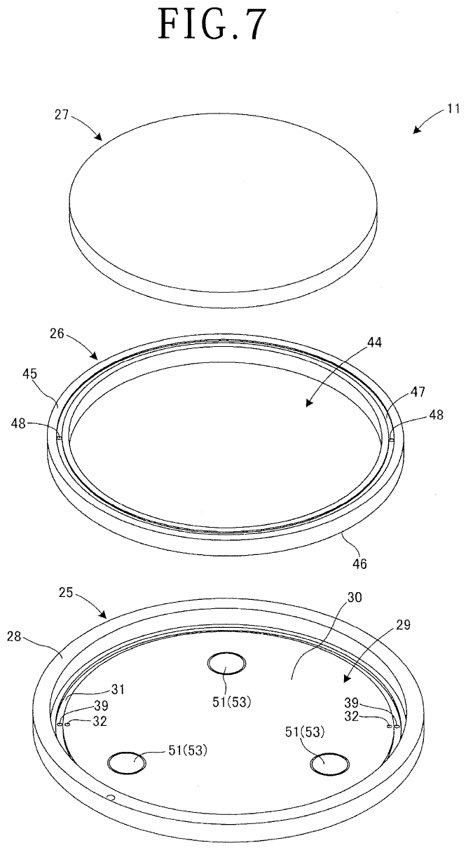

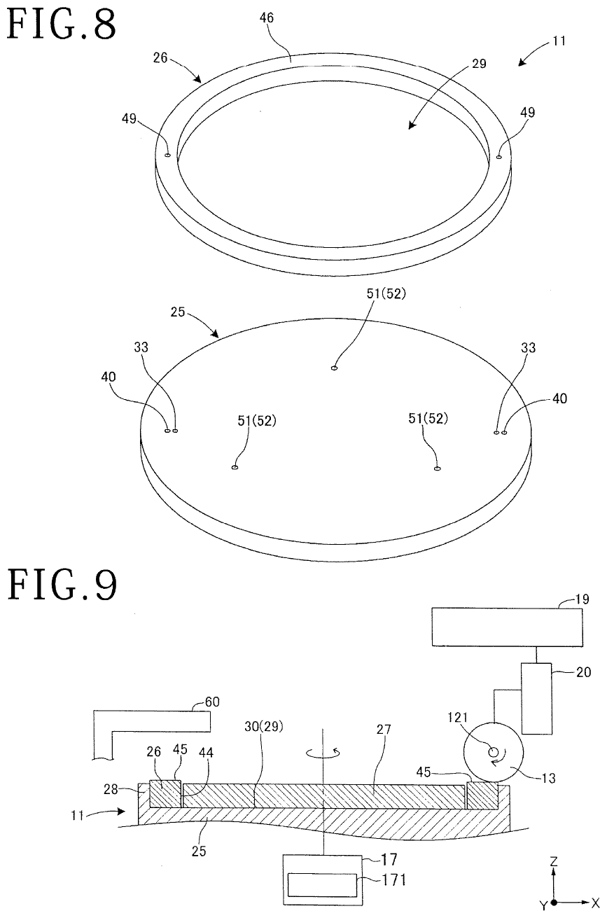

Subsequently, with reference to FIGS. 5 to 8, the detailed configuration of the chuck table 11 included in the edge trimming apparatus 10 will be described. FIGS. 5 and 6 illustrate the sectional structure of the chuck table 11. FIG. 7 is a perspective view of the chuck table 11 in a disassembled state as viewed from the upper side. FIG. 8 is a perspective view of the chuck table 11 in the disassembled state as viewed from the lower side. The chuck table 11 is a first embodiment of the chuck table to which the present invention is applied. The chuck table 11 includes a base table 25, the ring table 26, and a center table 27.

The base table 25 is rotatably supported by the table rotation mechanism 17 (FIGS. 2 and 3). A ring-shaped outer circumferential wall 28 and a recessed part 29 on the inside surrounded by the outer circumferential wall 28 are formed on the upper surface side of the base table 25. A horizontal support surface 30 is formed at a bottom part of the recessed part 29. A ring-shaped table suction recessed part 31 continuous in the circumferential direction of the base table 25 is formed at a peripheral part near the outer circumferential wall 28 in the support surface 30. The table suction recessed part 31 is a structure made by denting part of the recessed part 29 downward.

Communicating ports 32 are formed in the support surface 30. As illustrated in FIG. 7, a plurality of communicating ports 32 are made with the positions thereof made different in the circumferential direction of the base table 25. The individual communicating ports 32 are formed near the table suction recessed part 31 in the diameter direction of the base table 25. As illustrated in FIGS. 5 and 6, air flow paths 33 are connected to the communicating ports 32. The air flow paths 33 are each composed of an internal flow path formed inside the base table 25 and an external flow path disposed outside the base table 25. Holes that are the lower ends of the internal flow paths of the air flow paths 33 are formed in the lower surface of the base table 25 (see FIG. 8). The external flow paths of the air flow paths 33 each branch into a flow path communicating with an air source 36 through an open/close valve 35 and a flow path communicating with a suction source 38 through an open/close valve 37.

Table suction holes 39 are formed in a bottom part of the table suction recessed part 31, and table suction paths 40 are connected to the table suction holes 39. As illustrated in FIGS. 5 and 6, the table suction paths 40 are each composed of an internal flow path formed inside the base table 25 and an external flow path disposed outside the base table 25. Holes that are the lower ends of the internal flow paths of the table suction paths 40 are formed in the lower surface of the base table 25 (see FIG. 8). The external flow paths of the table suction paths 40 communicate with a suction source 43 through a suction path open/close valve 42.

As illustrated in FIGS. 7 and 8, as each of the communicating port 32, the air flow path 33, the table suction hole 39, and the table suction path 40, two elements are disposed at equal intervals (180° intervals) in the circumferential direction of the base table 25. Note that the number and arrangement of communicating ports 32, air flow paths 33, table suction holes 39, and table suction paths 40 are not limited thereto.

The ring table 26 is a ring-shaped table surrounding a circular center opening 44 that penetrates in the Z-axis direction, has the wafer suction surface 45 on the upper surface side, and has a lower surface 46 on the lower surface side. The ring table 26 is supported in the recessed part 29 of the base table 25 in the state in which the wafer suction surface 45 is exposed on the upper surface side. The diameter of the outer circumferential side surface of the ring table 26 is substantially the same as the diameter of the inner circumferential side surface of the outer circumferential wall 28. The ring table 26 is disposed in the recessed part 29 in the state in which the outer circumferential side surface of the ring table 26 is in contact with the inner circumferential side surface of the outer circumferential wall 28. Furthermore, the thickness of the ring table 26 in the Z-axis direction (distance from the wafer suction surface 45 to the lower surface 46) is larger than the depth of the recessed part 29 (distance from the upper surface of the outer circumferential wall 28 to the support surface 30). Thus, in the state in which the lower surface 46 of the ring table 26 is placed on the support surface 30 of the base table 25, the wafer suction surface 45 is located on the upper side relative to the upper surface of the outer circumferential wall 28 in a protruding manner.

In the present embodiment, the wafer W is a silicon wafer, and the ring table 26 is formed of silicon. Note that only the front surface side including the wafer suction surface 45 in the ring table 26 may be formed of silicon, and the part other than the front surface side may be formed of a material other than silicon. Due to forming at least the part including the wafer suction surface 45 in the ring table 26 by silicon, it is possible to execute the surface correction processing to planarize the wafer suction surface 45 by using the abrasive stone 13 that grinds the outer circumferential part of the wafer W (edge trimming). That is, the grinding of the wafer W and the surface correction processing of the wafer suction surface 45 can be executed without requiring replacement of the abrasive stone 13. Thus, after the wafer W is held on the chuck table 11 and grinding processing of the outer circumferential part of the upper surface Wa of the wafer W is executed by the abrasive stone 13, the wafer suction surface 45 can be ground to be corrected to an even height by processing with the abrasive stone 13 before the chuck table 11 is caused to hold the next wafer W.

A ring-shaped wafer suction recessed part 47 continuous in the circumferential direction of the ring table 26 is formed in the wafer suction surface 45 of the ring table 26. The wafer suction recessed part 47 hollows downward relative to the wafer suction surface 45. Wafer suction holes 48 are formed in a bottom part of the wafer suction recessed part 47. As illustrated in FIG. 7, a plurality of wafer suction holes 48 are made with the positions thereof made different in the circumferential direction of the ring table 26. As illustrated in FIGS. 5 and 6, air flow paths 49 passing inside the ring table 26 are connected to the wafer suction holes 48. The air flow paths 49 are opened in the lower surface 46 of the ring table 26 (see FIG. 8).

As illustrated in FIGS. 7 and 8, as each of the wafer suction hole 48 and the air flow path 49, two elements are disposed at equal intervals (180° intervals) in the circumferential direction of the ring table 26. Note that the number and arrangement of wafer suction holes 48 and air flow paths 49 are not limited thereto.

When the suction path open/close valve 42 is opened and the suction source 43 is driven in the state in which the lower surface 46 of the ring table 26 is placed on the support surface 30 of the base table 25, air in the table suction recessed part 31 is sucked through the table suction holes 39 and the table suction paths 40. By this suction force, the lower surface 46 of the ring table 26 is sucked and held by the support surface 30. That is, the chuck table 11 includes a ring table holding mechanism 50 that causes the suction force to act on the support surface 30 and causes the base table 25 to hold the ring table 26. The table suction holes 39, the table suction paths 40, the suction path open/close valve 42, the suction source 43, and so forth form the ring table holding mechanism 50.

In the ring table holding mechanism 50 of the present embodiment, the table suction recessed part 31 with the ring shape is formed in the support surface 30, and the table suction holes 39 are formed inside the table suction recessed part 31. This allows the suction force to act on the whole of the ring table 26 in the circumferential direction and allows the ring table 26 to be stably held by the support surface 30.

When the ring table 26 is sucked and held on the base table 25, the position of the ring table 26 relative to the base table 25 in the circumferential direction is set in such a manner that the air flow paths 49 of the ring table 26 communicate with the communicating ports 32 (air flow paths 33) of the base table 25. That is, disposing of the ring table 26 in the circumferential direction is set in such a manner that the wafer suction holes 48 of the ring table 26 communicate with the air source 36 or the suction source 38 through the air flow paths 49 and the air flow paths 33. To allow this setting position to be easily settled, a positioning mechanism that limits, in advance, the circumferential position at which the ring table 26 can be attached and detached to and from the base table 25 may be disposed. As one example, a groove extending along the Z-axis direction is made in one of the inner circumferential side surface of the outer circumferential wall 28 of the base table 25 and the outer circumferential side surface of the ring table 26, and a protrusion that can be inserted into the groove is disposed on the other. The position of the ring table 26 in the circumferential direction of the base table 25 can be settled by engagement between the groove and the protrusion.

When the open/close valve 37 is opened and the suction source 38 is driven in the state in which disposing of the ring table 26 is set as above, air in the wafer suction recessed part 47 is sucked through the wafer suction holes 48, the air flow paths 49, the communicating ports 32, and the air flow paths 33, and a suction force acts on the wafer suction surface 45. Moreover, when the open/close valve 35 is opened and the air source 36 is driven, air is supplied to the wafer suction recessed part 47 through the wafer suction holes 48, the air flow paths 49, the communicating ports 32, and the air flow paths 33, and the air is ejected to the wafer suction surface 45.

The center table 27 is a table with a circular plate shape with such a size as to be put inside the center opening 44 of the ring table 26. The thickness in the Z-axis direction regarding the ring table 26 (distance from the wafer suction surface 45 to the lower surface 46) in the initial state in which the ring table 26 has not been ground by the abrasive stone 13 is larger than the thickness of the center table 27 in the Z-axis direction.

The chuck table 11 includes lift mechanisms 51 that support the center table 27 in such a manner as to be capable of raising and lowering the center table 27 in the Z-axis direction relative to the base table 25. The lift mechanisms 51 are each formed of an air cylinder. Specifically, cylinder spaces 52 are formed inside the base table 25, and pistons 53 are supported inside the cylinder spaces 52. The upper ends of the pistons 53 are in contact with the bottom surface of the center table 27. As illustrated in FIGS. 7 and 8, three lift mechanisms 51 are disposed at equal intervals (120° intervals) in the circumferential direction of the base table 25. Note that the number and arrangement of lift mechanisms 51 are not limited thereto.

As illustrated in FIGS. 5 and 6, the lower ends of the cylinder spaces 52 are opened on the lower surface side of the base table 25, and an air flow path 54 is connected to the lower ends of the cylinder spaces 52. The air flow path 54 is connected to a table raising-lowering valve 55. The table raising-lowering valve 55 operates into a suction state (FIG. 5) in which the air flow path 54 is connected to a suction source 56 and an air supply state (FIG. 6) in which the air flow path 54 is connected to an air source 57.

As illustrated in FIG. 5, when the table raising-lowering valve 55 is set to the suction state and the suction source 56 is operated, air in the cylinder spaces 52 is sucked through the air flow path 54, and the pistons 53 lower. Thus, the center table 27 supported by the pistons 53 lowers. Because the thickness of the ring table 26 in the Z-axis direction is larger than the thickness of the center table 27, the upper surface of the center table 27 is located on the lower side relative to the wafer suction surface 45 of the ring table 26 in the state in which the lower surface of the center table 27 that has lowered is placed on the support surface 30. That is, in the upper surface of the chuck table 11, the wafer suction surface 45 of the ring table 26 is located on the uppermost side.

As illustrated in FIG. 6, when the table raising-lowering valve 55 is set to the air supply state and the air source 57 is operated, air is supplied to the cylinder spaces 52 through the air flow path 54, and the pistons 53 rise. Thus, the center table 27 supported by the pistons 53 rises. This makes the state in which the upper surface of the center table 27 is located on the upper side relative to the wafer suction surface 45 of the ring table 26.

In this manner, the lift mechanisms 51 each move the piston 53 in the Z-axis direction through suction and supply of air in the cylinder space 52 to raise and lower the center table 27 relative to the base table 25. When the chuck table 11 holds the wafer W, in the state in which the center table 27 is lowered by the lift mechanisms 51, the lower surface Wb of the wafer W is supported by the wafer suction surface 45 of the ring table 26, and a gap exists between the upper surface of the center table 27 and the lower surface Wb of the wafer W (see FIG. 5). In the state in which the center table 27 has risen, the upper surface of the center table 27 supports the lower surface Wb of the wafer W and pushes the wafer W upward, so that the lower surface Wb of the wafer W is separated from the wafer suction surface 45 of the ring table 26.

When the outer circumferential part of the wafer W is ground by the abrasive stone 13, as illustrated in FIGS. 2 and 5, by control by the controller 14, the lift mechanisms 51 are operated to lower the center table 27, and the lower surface Wb of the wafer W is placed on the wafer suction surface 45 of the ring table 26. Furthermore, by control by the controller 14, the open/close valve 37 is opened, and the suction source 38 is driven to cause a suction force to act on the wafer suction surface 45 and suck and hold the wafer W on the wafer suction surface 45. In this state, the controller 14 controls the Y-axis movement mechanism 19, the Z-axis movement mechanism 20, and the edge trimming mechanism 12. Thereby, the abrasive stone 13 is positioned above the outer circumferential part of the wafer W, the spindle motor 123 is driven to rotate the abrasive stone 13, and the edge trimming mechanism 12 is lowered by the Z-axis movement mechanism 20. Furthermore, the controller 14 drives the motor 171 of the table rotation mechanism 17 to rotate the chuck table 11. By the above operation of the respective parts, the abrasive stone 13 that rotates around the spindle 121 as the axis along the horizontal direction gets contact with the outer circumferential part of the wafer W held on the chuck table 11 that rotates around the axis along the Z-axis direction, and the outer circumferential part of the upper surface Wa of the wafer W is ground in a ring manner by the abrasive stone 13.

When the grinding of the outer circumferential part of the upper surface Wa of the wafer W by the abrasive stone 13 has been completed, as illustrated in FIG. 6, by control by the controller 14, the open/close valve 35 is opened, and the air source 36 is driven to eject air from the wafer suction holes 48 and allow the wafer W sucked by the wafer suction surface 45 to separate from the wafer suction surface 45. Moreover, by control by the controller 14, the lift mechanisms 51 are operated to raise the center table 27, and the center table 27 pushes up the lower surface Wb of the wafer W. The outer circumferential part (remaining part that has not been ground by the abrasive stone 13) of the wafer W pushed up by the center table 27 separates from the ring table 26 upward. The conveying mechanism includes an edge clamp (illustration is omitted) that grasps the outer circumferential edge of the wafer W and carries out the wafer W grasped by the edge clamp from the chuck table 11.

When the wafer W is ground by the abrasive stone 13 in the edge trimming apparatus 10, the outer circumferential part of the lower surface Wb of the wafer W needs to be stably supported, and it is required that the wafer suction surface 45 of the ring table 26 be flat. In the edge trimming apparatus 10, it is possible to execute processing of grinding and planarizing, by the abrasive stone 13, the wafer suction surface 45 of the ring table 26 in the state in which it does not hold the wafer W.

In the case of grinding and planarizing the wafer suction surface 45 of the ring table 26 by the abrasive stone 13, the controller 14 controls the lift mechanisms 51 to set the center table 27 to a lowered state as in FIG. 3. That is, the state in which the wafer suction surface 45 of the ring table 26 is located on the upper side relative to the upper surface of the center table 27 is made. Subsequently, the controller 14 controls the Y-axis movement mechanism 19, the Z-axis movement mechanism 20, and the edge trimming mechanism 12. Thereby, the abrasive stone 13 is positioned above the ring table 26, the spindle motor 123 is driven to rotate the abrasive stone 13, and the edge trimming mechanism 12 is lowered by the Z-axis movement mechanism 20.

When the edge trimming mechanism 12 lowers and the abrasive stone 13 gets contact with the wafer suction surface 45 of the ring table 26 while rotating, the wafer suction surface 45 is ground by the abrasive stone 13. The wafer suction surface 45 can be planarized, and the shape thereof can be corrected by relatively moving the chuck table 11 and the edge trimming mechanism 12 in such a manner that the abrasive stone 13 gets contact with the whole of the wafer suction surface 45 (excluding the formation region of the wafer suction recessed part 47).

In the configuration example illustrated in FIGS. 3 and 4, the abrasive stone 13 is in contact with the wafer suction surface 45 on a virtual line Pa that passes through the center of the ring table 26 and extends along the Y-axis direction, and the spindle 121 that rotatably supports the abrasive stone 13 extends along the Y-axis direction. In this configuration example, the place at which the abrasive stone 13 is in contact with the wafer suction surface 45 can be changed in the radial direction of the ring table 26 by moving the edge trimming mechanism 12 in the Y-axis direction by the Y-axis movement mechanism 19. Furthermore, the place at which the abrasive stone 13 is in contact with the wafer suction surface 45 can be changed in the circumferential direction of the ring table 26 by rotating the chuck table 11 by the table rotation mechanism 17. Therefore, when causing the abrasive stone 13 to grind the wafer suction surface 45, the controller 14 combines the movement of the edge trimming mechanism 12 in the Y-axis direction by the Y-axis movement mechanism 19 and the rotation of the chuck table 11 by the table rotation mechanism 17 to grind the whole of the wafer suction surface 45 by the abrasive stone 13.

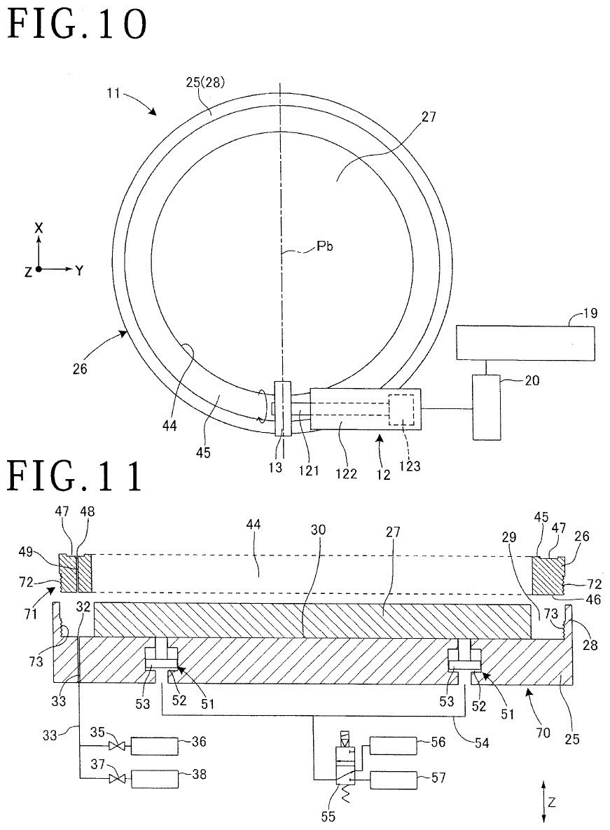

FIGS. 9 and 10 illustrate a modification example in which the disposing of the edge trimming mechanism 12 relative to the chuck table 11 is changed. Specifically, the abrasive stone 13 is in contact with the wafer suction surface 45 on a virtual line Pb that passes through the center of the ring table 26 and extends along the X-axis direction, and the spindle 121 that rotatably supports the abrasive stone 13 extends along the Y-axis direction. In this configuration example, the place at which the abrasive stone 13 is in contact with the wafer suction surface 45 can be changed in the radial direction of the ring table 26 by moving the chuck table 11 in the X-axis direction by the X-axis movement mechanism 16 (FIG. 1). Furthermore, the place at which the abrasive stone 13 is in contact with the wafer suction surface 45 can be changed in the circumferential direction of the ring table 26 by rotating the chuck table 11 by the table rotation mechanism 17. Therefore, when causing the abrasive stone 13 to grind the wafer suction surface 45, the controller 14 combines the movement of the chuck table 11 in the X-axis direction by the X-axis movement mechanism 16 and the rotation of the chuck table 11 by the table rotation mechanism 17 to grind the whole of the wafer suction surface 45 by the abrasive stone 13.

Moreover, by grinding the wafer suction surface 45 with the disposing of FIGS. 9 and 10, the lower surface of the abrasive stone 13 as well as the wafer suction surface 45 can be made flat.

When the wafer suction surface 45 is ground, the height of the ring table 26 in the Z-axis direction decreases according to the amount of grinding. In the state in which the ring table 26 is a new product and the wafer suction surface 45 has not been ground, the wafer suction surface 45 exists at a position higher than the upper surface of the center table 27. The difference in the height between the wafer suction surface 45 and the upper surface of the center table 27 in this state is the grinding-possible amount of the wafer suction surface 45 in the Z-axis direction. If the wafer suction surface 45 is ground beyond this grinding-possible amount, the state in which the upper surface of the center table 27 protrudes to the upper side relative to the wafer suction surface 45 is made when the center table 27 is positioned to the lowering position (FIGS. 4 and 5). If the wafer W is supported by the chuck table 11 in this state, the lower surface Wb of the wafer W is supported by the upper surface of the center table 27, and a gap exists between the lower surface Wb of the wafer W and the wafer suction surface 45. Therefore, it becomes impossible to properly hold, by the ring table 26, the outer circumferential part of the lower surface Wb of the wafer W as the target of grinding, and processing failure occurs. Thus, the ring table 26 ground by the above-described grinding-possible amount is removed from the base table 25 and is replaced by the new ring table 26.

The edge trimming apparatus 10 includes a height detector 60 (FIG. 1, FIG. 3, and FIG. 9). The height detector 60 detects the height of the wafer suction surface 45 of the ring table 26 and the support surface 30 of the base table 25. For example, as the height detector 60, a contactless-type position sensor that measures the height from the result of application of light, electromagnetic waves, ultrasonic waves, or the like to a measurement target and reflection thereof, a contact-type height gauge that executes measurement by directly bringing a measurement probe into contact with a measurement target, or the like can be applied.

The controller 14 stores the height of the support surface 30 measured by the height detector 60 in a storage section 61 (FIG. 1). The measurement of the height of the support surface 30 can be executed at a timing when the support surface 30 is exposed, such as when the ring table 26 has been removed from the base table 25. Alternatively, it is also possible to form the center table 27 by a translucent material and project light from the upper side of the center table 27 and detect the light reflected by the support surface 30 to measure the height of the support surface 30.

The controller 14 includes a thickness calculation section 62 (FIG. 1). The controller 14 measures the height of the wafer suction surface 45 of the ring table 26 by the height detector 60 at a predetermined timing, and the thickness calculation section 62 calculates the difference between the measured height of the wafer suction surface 45 and the height of the support surface 30 stored in the storage section 61 as the thickness of the ring table 26. The timing of the measurement of the height of the wafer suction surface 45 can be optionally set. For example, the height of the wafer suction surface 45 is measured after the wafer suction surface 45 is ground by the abrasive stone 13.

The controller 14 includes a determination section 63 (FIG. 1). The determination section 63 determines the timing at which the thickness of the ring table 26 calculated by the thickness calculation section 62 has become equal to or smaller than a threshold set in advance as the replacement timing of the ring table 26. This threshold is set in such a manner that the thickness of the ring table 26 is kept from becoming smaller than the thickness of the center table 27 and the depth of the recessed part 29.

When the determination section 63 determines that the replacement timing of the ring table 26 has come, the controller 14 causes an informing section 64 (FIG. 1) to inform that the replacement timing of the ring table 26 has come. The informing section 64 is, for example, a display monitor, an indicator lamp, a speaker, or the like included in the edge trimming apparatus 10 and executes informing by information display on the display monitor, change in the lighting form or the color of the indicator lamp, sound making from the speaker, or the like. Alternatively, the edge trimming apparatus 10 may include a communication part that can communicate with external equipment such as a server or a portable information terminal, and a signal may be transmitted from the communication part of the edge trimming apparatus 10 to the external equipment to inform that the replacement timing of the ring table 26 has come by using the external equipment. Upon receiving the informing, a worker who executes operation or maintenance of the edge trimming apparatus 10 executes replacement work of the ring table 26.

As above, the chuck table 11 included in the edge trimming apparatus 10 is configured to allow replacement of only the ring table 26, which supports the outer circumferential part of the lower surface Wb of the wafer W. Therefore, the number and cost of replacement parts can be reduced.

Furthermore, the ring table holding mechanism 50 in the chuck table 11 is the configuration that sucks and hold the ring table 26 on the support surface 30 of the base table 25. Therefore, releasing the suction holding makes the state in which the ring table 26 can be removed. Thus, the ring table 26 can be easily replaced.

Moreover, the upper surface of the ring table 26 is ground to form and correct the wafer suction surface 45 by using the abrasive stone 13 that grinds the outer circumferential part of the upper surface Wa of the wafer W. Thus, replacement work of the abrasive stone for grinding the upper surface of the ring table 26 becomes unnecessary. Therefore, after the wafer W is processed by using the abrasive stone 13, the wafer suction surface 45 can be ground to be corrected to an even height by using the abrasive stone 13 before the chuck table 11 is caused to hold the next wafer W. Furthermore, by correcting (planarizing) the wafer suction surface 45 into the even height by grinding using the abrasive stone 13, the ring table 26 is allowed to hold the outer circumferential part of the lower surface Wb of the wafer W with the even height. Therefore, it is possible to eliminate the need for the step of measuring the height of the outer circumferential part of the wafer W in a ring manner before grinding processing of the outer circumferential part of the upper surface Wa of the wafer W.

Subsequently, a chuck table 70 of a second embodiment will be described with reference to FIGS. 11 to 13. In this chuck table 70, a ring table holding mechanism 71 that causes the base table 25 to hold the ring table 26 is different from the ring table holding mechanism 50 in the above-described chuck table 11. In description of the chuck table 70, a configuration common to the chuck table 11 previously described is indicated by the same numeral, and description thereof is omitted.

The ring table holding mechanism 71 of the chuck table 70 includes a male screw 72 formed at a lower part of the outer circumferential side surface (outer side surface) of the ring table 26 and a female screw 73 formed at a lower part of the inner circumferential side surface (inner side surface) of the outer circumferential wall 28 forming the recessed part 29 of the base table 25. The male screw 72 and the female screw 73 are screws conforming to standards compatible with each other. The ring table 26 is held in the recessed part 29 by screwing the male screw 72 to the female screw 73.

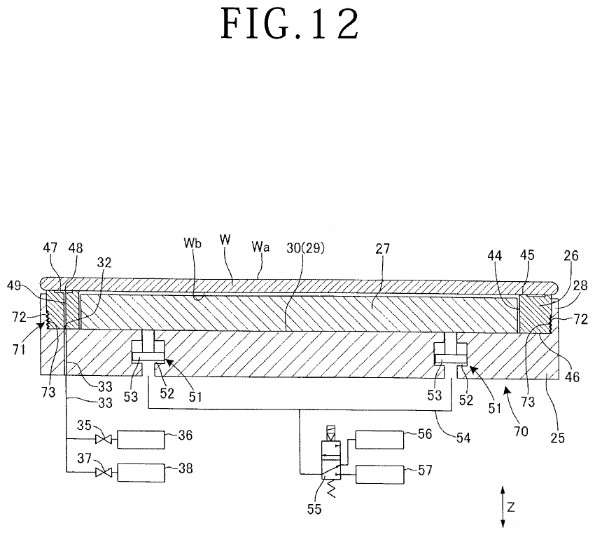

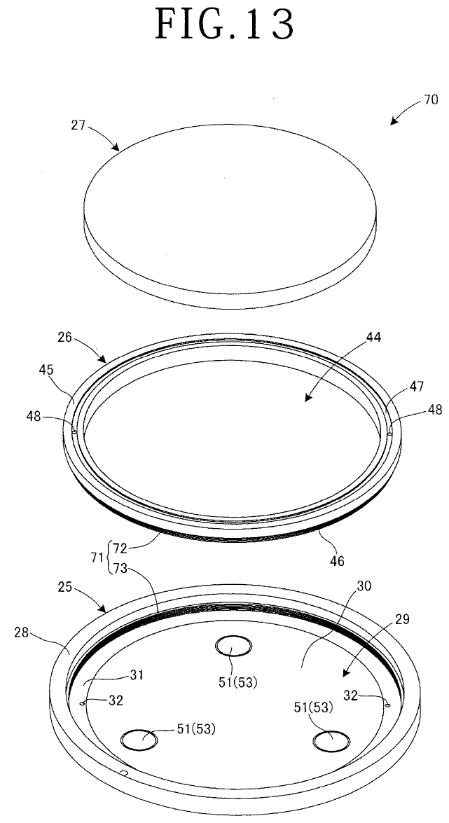

The configuration is made in such a manner that, when the male screw 72 is screwed to the female screw 73 until the lower surface 46 of the ring table 26 gets contact with the support surface 30, the positions of the air flow path 49 of the ring table 26 and the communicating port 32 (air flow path 33) of the base table 25 in the circumferential direction of the chuck table 11 correspond with each other and the air flow paths 49 communicate with the communicating ports 32 (air flow paths 33). Therefore, in the state in which the male screw 72 and the female screw 73 are screwed and the ring table 26 is held in the recessed part 29 as in FIG. 12, the wafer W can be sucked and held on the wafer suction surface 45 by opening the open/close valve 37 and driving the suction source 38 to suck air from the wafer suction holes 48. Moreover, by opening the open/close valve 35 and driving the air source 36, air can be ejected from the wafer suction holes 48, and the suction holding of the wafer W to the wafer suction surface 45 can be released.

As illustrated in FIGS. 11 and 13, the ring table 26 can be removed from the recessed part 29 of the base table 25 by releasing the screwing of the male screw 72 to the female screw 73.

As above, the chuck table 70 allows the ring table 26 to be attached and detached to and from the base table 25 by screwing operation. Thus, the ring table 26 can be replaced without requiring complicated operation. Furthermore, the ring table holding mechanism 71 does not include a structure for sucking and holding the ring table 26 on the base table 25, so that the ring table holding mechanism 71 is allowed to be a simple structure.

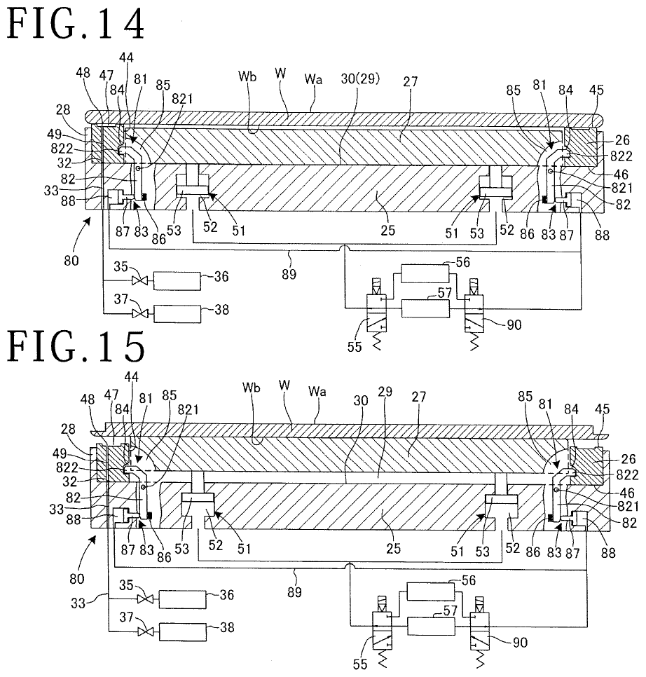

Subsequently, a chuck table 80 of a third embodiment will be described with reference to FIGS. 14 to 17. In the chuck table 80, a ring table holding mechanism 81 that causes the base table 25 to hold the ring table 26 is different from the ring table holding mechanisms 50 and 71 in the above-described chuck tables 11 and 70. In description of the chuck table 80, a configuration common to the chuck table 11 previously described is indicated by the same numeral, and description thereof is omitted.

The ring table holding mechanism 81 includes clamps 82 (grasping parts) disposed in the base table 25 and opening-closing mechanisms 83 (opening-closing units) that open and close the clamps 82. At least three clamps 82 are disposed at equal intervals with the positions thereof made different in the circumferential direction of the chuck table 80. The individual clamps 82 are each supported pivotally around a shaft 821 along the horizontal direction.

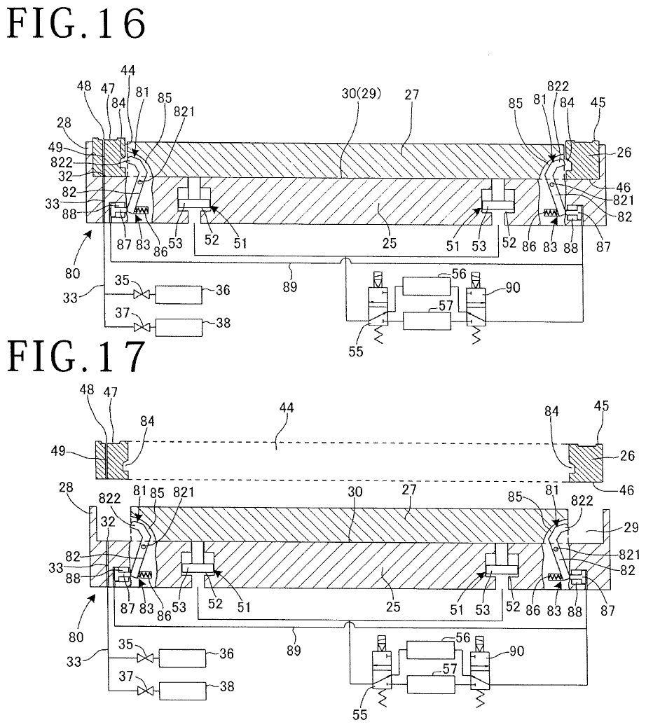

Part of the clamp 82 protrudes upward from the support surface 30 of the base table 25 and has a claw 822 at the tip. Engagement recessed parts 84 with which the claw 822 of the clamp 82 can engage are formed in the inner circumferential side surface of the ring table 26. By a pivot around the shaft 821, the clamps 82 each execute opening-closing operation to a holding position (FIGS. 14 and 15) at which the claw 822 engages with the engagement recessed part 84 and a holding release position (FIGS. 16 and 17) at which the claw 822 separates from the engagement recessed part 84. To avoid interference with the opening-closing operation of the clamps 82, notches 85 that part of the clamp 82 enters are formed on the lower side of the outer circumference of the center table 27.

In the state in which the clamps 82 exist at the holding position, the claws 822 engage with the engagement recessed parts 84 in the inner circumferential side surface of the ring table 26, and the ring table 26 is held in the recessed part 29 of the base table 25. In the state in which the clamps 82 exist at the holding release position, the claws 822 are disengaged from the engagement recessed parts 84 and the clamping by the clamps 82 is released. Thus, the ring table 26 can be attached and detached to and from the recessed part 29 of the base table 25.

The opening-closing mechanisms 83 each bias the clamp 82 toward the holding release position by a biasing member 86. The biasing members 86 are, for example, compression springs housed in the base table 25 and each push a part around an end part on the opposite side to the claw 822 in the clamp 82 to bias the clamp 82 toward the holding release position.

The opening-closing mechanisms 83 each push, by a pressing member 87, the clamp 82 in the opposite direction to the direction of the biasing by the biasing member 86 to cause the clamp 82 to pivot to the holding position. The pressing members 87 are disposed in cylinder spaces 88 formed inside the base table 25 and are supported movably in the horizontal direction. The lower ends of the cylinder spaces 88 are opened on the lower surface side of the base table 25, and an air flow path 89 is connected to the lower ends of the cylinder spaces 88. The air flow path 89 is connected to a clamp open/close valve 90. The clamp open/close valve 90 operates into an air supply state (FIGS. 14 and 15) in which the air flow path 89 is connected to the air source 57 and a suction state (FIGS. 16 and 17) in which the air flow path 89 is connected to the suction source 56.

As illustrated in FIGS. 14 and 15, when the clamp open/close valve 90 is set to the air supply state and the air source 57 is operated, air is supplied to the cylinder spaces 88 through the air flow path 89 and the pressing members 87 are pushed due to the pressure of the air in the cylinder spaces 88. Thereupon, the pressing members 87 each push the clamp 82 in the opposite direction to the direction of the biasing by the biasing member 86, and the clamps 82 pivot to the holding position.

In the state in which the clamps 82 exist at the holding position, the ring table 26 is held by the base table 25 due to engagement between the claws 822 and the engagement recessed parts 84. Thus, the wafer W can be held on the wafer suction surface 45 of the ring table 26 as illustrated in FIG. 14. In addition, in the state in which the wafer W is held on the wafer suction surface 45, edge trimming in which the outer circumferential part of the upper surface Wa of the wafer W is ground by the abrasive stone 13 can be executed.

Furthermore, after the outer circumferential part of the upper surface Wa of the wafer W is ground by the abrasive stone 13, the wafer W can be separated from the wafer suction surface 45 of the ring table 26 by raising the center table 27 with use of the lift mechanisms 51 as illustrated in FIG. 15. At this time, because the clamps 82 exist at the holding position and hold the ring table 26, the ring table 26 does not make a rise following the center table 27 but continues to be held in the recessed part 29.

In the case of forming and correcting the wafer suction surface 45 of the ring table 26 by grinding by the abrasive stone 13, the processing is executed in the state in which the clamps 82 are set to the holding position, and the ring table 26 is held by the base table 25 similarly to the case of the edge trimming of the outer circumferential part of the wafer W (FIG. 14). This can form the wafer suction surface 45 with high accuracy without unexpected movement of the ring table 26 relative to the base table 25.

As illustrated in FIG. 16, when the clamp open/close valve 90 is set to the suction state and the suction source 56 is operated, air in the cylinder spaces 88 is sucked through the air flow path 89 and the pressing members 87 are drawn into the cylinder spaces 88. Thereupon, the pressing members 87 each release the pushing against the clamp 82 and the clamps 82 pivot to the holding release position by the biasing force of the biasing member 86.

When the clamps 82 pivot to the holding release position, the clamping of the ring table 26 by the clamps 82 is released. Thus, the ring table 26 can be removed from the recessed part 29 of the base table 25 as illustrated in FIG. 17. In the state in which the clamps 82 exist at the holding release position, the claws 822 are housed in the notches 85 of the center table 27 and thus operation of attachment or detachment of the ring table 26 into or from the recessed part 29 is not impeded by the claw 822. That is, the ring table 26 can be easily removed by only being pulled out upward.

As above, in the chuck table 80, holding of the ring table 26 on the base table 25 and release of the holding are executed by the opening-closing operation of the clamps 82 included in the ring table holding mechanism 81, and the ring table 26 can be attached and detached to and from the base table 25 in the state in which the holding by the clamps 82 has been released. In the ring table holding mechanism 81, the opening-closing mechanisms 83 that each cause the clamp 82 to execute the opening-closing operation are formed with the air cylinders using the suction and supply structure (the suction source 56 and the air source 57) of air in the lift mechanisms 51 that raise and lower the center table 27, and dedicated suction source and air source are not required. Therefore, the ring table holding mechanism 81 is allowed to be a simple structure.

In the illustrated chuck table 80, the inner circumferential side surface (engagement recessed parts 84) of the ring table 26 is clamped by the clamps 82. However, a structure in which the outer circumferential side surface of the ring table 26 is clamped by clamps may be employed. As one example, brackets that each pivotally support a clamp are disposed on the outer circumferential side surface of the base table 25, and the clamps are attached to the outside of the base table 25 with the interposition of the brackets. Opening parts through which a claw of the clamp can pass are made at part of the outer circumferential wall 28 of the base table 25. Furthermore, engagement recessed parts with which the claw of the clamp can engage are made in the outer circumferential side surface of the ring table 26. In addition, when the clamps pivot, the claws of the clamps each pass through the opening part of the outer circumferential wall 28 and engage with the engagement recessed parts of the outer circumferential side surface of the ring table 26, and the ring table 26 is held in the recessed part 29.

According to the chuck tables 11, 70, and 80 described above, the configuration is made in such a manner that only the ring table 26 can be replaced. Thus, the number of replacement parts can be reduced, and manufacturing and maintenance can be inexpensively executed. Moreover, the wafer suction surface 45 of the ring table 26 is formed and corrected by the abrasive stone 13 that grinds the outer circumferential part of the upper surface Wa of the wafer W. This eliminates the need for replacement work of the abrasive stone for grinding the wafer suction surface 45 of the ring table 26 and the step of measuring the height of the outer circumferential part of the wafer W in a ring manner before grinding processing of the outer circumferential part of the upper surface Wa of the wafer W. Thus, efficient processing can be implemented.

As the configuration for holding the ring table 26 on the base table 25, the air suction structure is applied in the ring table holding mechanism 50 of the chuck table 11. The screwing structure is applied in the ring table holding mechanism 71 of the chuck table 70. The clamp structure is applied in the ring table holding mechanism 81 of the chuck table 80. In all configurations, holding of the ring table 26 and release of the holding can be executed without requiring complicated operation, and the ring table 26 can be easily replaced.

It is preferable that at least a front surface part (particularly the wafer suction surface 45) of the ring table 26 be formed of silicon, which is the same material as the wafer W made of silicon, as in the above-described embodiments. When the materials of the wafer W and the ring table 26 are common, grinding of the wafer W and grinding of the wafer suction surface 45 can be executed without requiring replacement of the abrasive stone, which provides high efficiency. However, in the present invention, the material of the ring table is not limited to silicon.

Furthermore, the wafer suction surface 45 of the ring table 26 may be formed with a porous component. That is, the lower surface side of the ring table 26 may be formed of a dense body, and the lower surface of the ring table 26 formed of the dense body may be sucked and held by a support surface. Moreover, in the case of holding the ring table 26 by the screwing system or the clamp system, the whole of the ring table 26 may be formed of the porous component.

Furthermore, in the above-described embodiments, the outer circumferential part of the upper surface Wa of the wafer W sucked and held by the wafer suction surface 45 is ground to a predetermined depth. However, the wafer may be a bonded wafer obtained by bonding two wafers to each other. In the case of the bonded wafer, the lower wafer is sucked and held by the wafer suction surface 45, and grinding is started from an outer circumferential part of the upper surface of the upper wafer and is executed until the outer circumferential part disappears. In the grinding, the outer circumferential part of the upper wafer is removed by the grinding to expose the upper surface of the lower wafer.

Note that embodiments of the present invention are not limited to the above-described embodiments and modification examples and may be variously changed, replaced, or modified without departing from the gist of technical ideas of the present invention. Moreover, if a technical idea of the present invention can be implemented in another way on the basis of advancement of a technique or another technique that is derivative, the technical idea may be carried out by using the method. Therefore, the scope of claims covers all embodiment modes that can be included in the range of technical ideas of the present invention.

As described above, according to the chuck table and the edge trimming apparatus of the present invention, height measurement at measurement points on a ring shape at an outer circumferential part of the chuck table does not need to be executed before grinding processing of an outer circumferential part of a wafer held on the chuck table is executed. Thus, the processing efficiency of the edge trimming of the wafer can be improved.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A chuck table used for an edge trimming apparatus that grinds an outer circumferential part of an upper surface of a wafer in a ring manner by an abrasive stone and holding the wafer, the chuck table comprising:
a ring table that sucks and holds a lower surface of the outer circumferential part of the wafer by a wafer suction surface; and
a base table that holds the ring table in such a manner that the wafer suction surface is exposed, wherein
the base table includes a ring table holding mechanism that holds the ring table, a support surface that supports a lower surface of the ring table held by the ring table holding mechanism, and a communicating port that is formed in the support surface and causes the wafer suction surface of the ring table to communicate with a suction source,
the ring table includes a wafer suction hole having an opening in the wafer suction surface in such a manner as to be capable of connecting to the communicating port, and
the wafer suction surface is planarized by grinding the wafer suction surface by the abrasive stone.

2. The chuck table according to claim 1, wherein
at least a front surface part of the ring table is formed of silicon.

3. The chuck table according to claim 1, wherein
the ring table holding mechanism includes a clamp that clamps an outer circumferential side surface or an inner circumferential side surface of the ring table and an opening-closing mechanism that opens and closes the clamp.

4. An edge trimming apparatus comprising:
a chuck table that holds a wafer;
an edge trimming mechanism that grinds an outer circumferential part of an upper surface of the wafer held by the chuck table in a ring manner by an abrasive stone; and
a controller that controls the edge trimming mechanism, wherein
the chuck table includes a ring table that sucks and holds a lower surface of the outer circumferential part of the wafer by a wafer suction surface and a base table that holds the ring table in such a manner that the wafer suction surface is exposed,
the base table has a ring table holding mechanism that holds the ring table, a support surface that supports a lower surface of the ring table held by the ring table holding mechanism, and a communicating port that is formed in the support surface and causes the wafer suction surface of the ring table to communicate with a suction source,
the ring table has a wafer suction hole having an opening in the wafer suction surface in such a manner as to be capable of connecting to the communicating port, and
the ring table is mounted on the base table attachably and detachably.

5. The edge trimming apparatus according to claim 4, wherein
the base table has a table suction hole that is formed in the support surface and sucks the ring table, and
the ring table holding mechanism includes the table suction hole that is formed in the support surface of the base table and sucks the lower surface of the ring table, a table suction path that causes the table suction hole to communicate with a suction source, and a table suction path open/close valve disposed on the table suction path.

6. The edge trimming apparatus according to claim 4, wherein
the ring table holding mechanism includes
a male screw formed at a lower part of an outer side surface of the ring table, and
a female screw that corresponds to the male screw and is formed at a lower part of an inner side surface of a recessed part in which the ring table is disposed in the base table.

7. The edge trimming apparatus according to claim 4, wherein
the ring table holding mechanism includes
a grasping part that is disposed on a side of the base table and grasps a lower part of an outer side surface of the ring table supported by the support surface, and
an opening-closing unit that opens and closes the grasping part.

8. The edge trimming apparatus according to claim 4, further comprising:
a height detector that detects height of the wafer suction surface and the support surface, wherein
the controller has a storage section that stores the height of the support surface measured by the height detector, a thickness calculation section that calculates difference between the height of the wafer suction surface measured and the height of the support surface stored in the storage section as thickness of the ring table when the height of the wafer suction surface is measured, and a determination section that determines a timing at which the thickness calculated by the thickness calculation section has become equal to or smaller than a threshold set in advance as a replacement timing of the ring table.
